(19) United States
(12) Patent Application Publication
(10) Pub. No.: US 2026/0003264 A1
(43) Pub. Date: Jan. 1, 2026

(54) NANOIMPRINT LITHOGRAPHY MASK AND METHOD OF MANUFACTURING A SEMICONDUCTOR DEVICE

(71) Applicant: Taiwan Semiconductor Manufacturing Company, Ltd., Hsinchu (TW)

(72) Inventors: Yu-Luen DENG, Hsinchu (TW); Chih-Kai YANG, Hsinchu (TW); Chien-Cheng CHEN, Hsinchu (TW); Hsuan-Chin LU, Hsinchu (TW); Meng-Jung LEE, Hsinchu (TW); Ming-Feng SHIEH, Hsinchu (TW)

(73) Assignee: Taiwan Semiconductor Manufacturing Company, Ltd., Hsinchu (TW)

(21) Appl. No.: 18/937,811

(22) Filed: Nov. 5, 2024

Related U.S. Application Data
(60) Provisional application No. 63/666,553, filed on Jul. 1, 2024.

(51) Int. Cl. G03F 7/00; G03F 7/20

(52) U.S. Cl. CPC G03F 7/0002; G03F 7/2018

(57) ABSTRACT

A method of manufacturing a semiconductor device includes forming a resist layer over a substrate and contacting the resist layer with a mask. The mask includes: a device region including a device pattern at a first level, an overlapping region surrounding the device region and having a light absorption material at a second level, and a peripheral region surrounding the device region and the overlapping region, and including a light blocking material at a third level, wherein the first, second, and third levels are at different positions. The resist layer is exposed to actinic radiation through the mask. The mask is removed from the resist layer, and portions of the resist layer not exposed to the actinic radiation are removed.

### RELATED APPLICATION

This application claims priority to U.S. Provisional Patent Application No. 63/666,553 filed Jul. 1, 2024, the entire contents of which are incorporated herein by reference.

### BACKGROUND

Photolithography operations are one of the key operations in the semiconductor manufacturing process. Photolithography techniques include ultraviolet lithography, deep ultraviolet lithography, and extreme ultraviolet lithography (EUVL). While photolithographic techniques, such as EUVL provide high resolution patterns, they are very expensive techniques. It is desirable to reduce the cost of lithography.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A shows a plan view of a nanoimprint lithography mask according to embodiments of the present disclosure. FIGS. 1B and 1C are detailed views of a nanoimprint lithography mask contacting a resist according to embodiments of the present disclosure. FIG. 1D shows a plan view of a portion of a substrate with multiple overlapping pattern fields formed thereon.

FIGS. 2A and 2B show a plan view and cross-sectional view, respectively, of a nanoimprint lithography mask according to embodiments of the present disclosure.

FIGS. 3A and 3B show a plan view and cross-sectional view, respectively, of semiconductor device manufacturing operation using a nanoimprint lithography mask according to embodiments of the present disclosure.

FIGS. 4A and 4B show a plan view and cross-sectional view, respectively, of semiconductor device manufacturing operation using a nanoimprint lithography mask according to embodiments of the present disclosure.

FIG. 5A shows a plan view of a nanoimprint lithography mask and a portion of a substrate with a resist layer on a substrate corresponding to a frame region of the mask, and a graph showing the resist layer thickness at the field edge of the substrate according to embodiments of the present disclosure. FIG. 5B shows a plan view of a patterned region of a substrate illustrating shot overlapping according to some embodiments of the present disclosure.

FIGS. 6A, 6B, 6C, 6D, 6F, and 6G schematically illustrate sequential operations of manufacturing a semiconductor device according to embodiments of the disclosure.

FIGS. 7A, 7B, 7C, 7D, 7F, 7G, and 7H schematically illustrate sequential operations of manufacturing a semiconductor device according to embodiments of the disclosure.

FIG. 8 shows a flowchart of a method of manufacturing a semiconductor device in accordance with embodiments of the present disclosure.

FIG. 9 shows a flowchart of a method of manufacturing a semiconductor device in accordance with embodiments of the present disclosure.

FIG. 10 shows a flowchart of a method of manufacturing a semiconductor device in accordance with embodiments of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described. Furthermore, the term “based” means that the composition, compound, or alloy contains 50 wt. % or more by weight of the material on which it is based.

Embodiments of the present disclosure provide a method of manufacturing a semiconductor device and a nanoimprint lithography mask for use in a method of manufacturing a semiconductor device. More specifically, the present disclosure provides techniques to prevent or suppress damage to nanoimprint lithography masks. In addition, embodiments of the present disclosure enable more efficient use of the pattern fields of the substrate because gaps between pattern fields can be eliminated. Furthermore, uncured, residual resist can be easily removed from overlapped areas of the pattern fields.

Nanoimprint lithography has been proposed as a lower cost alternative to extreme ultraviolet (EUV) lithography to form nanometer scale device features. The present disclosure provides a nanoimprint lithography mask less susceptible to damage during the pattern forming process, and therefore having a longer service life than other nanoimprint lithography masks. The nanoimprint lithography masks of the present disclosure also provide increased device yield according to embodiments of the disclosure. Nanoimprint lithography masks are also referred to as replicas and stamps, and such terms are used interchangeably in the present disclosure.

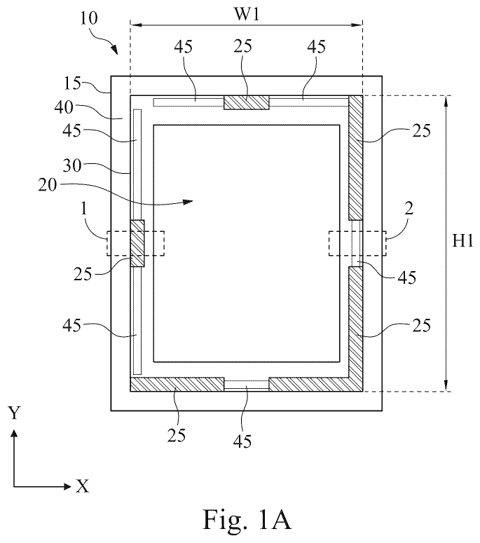

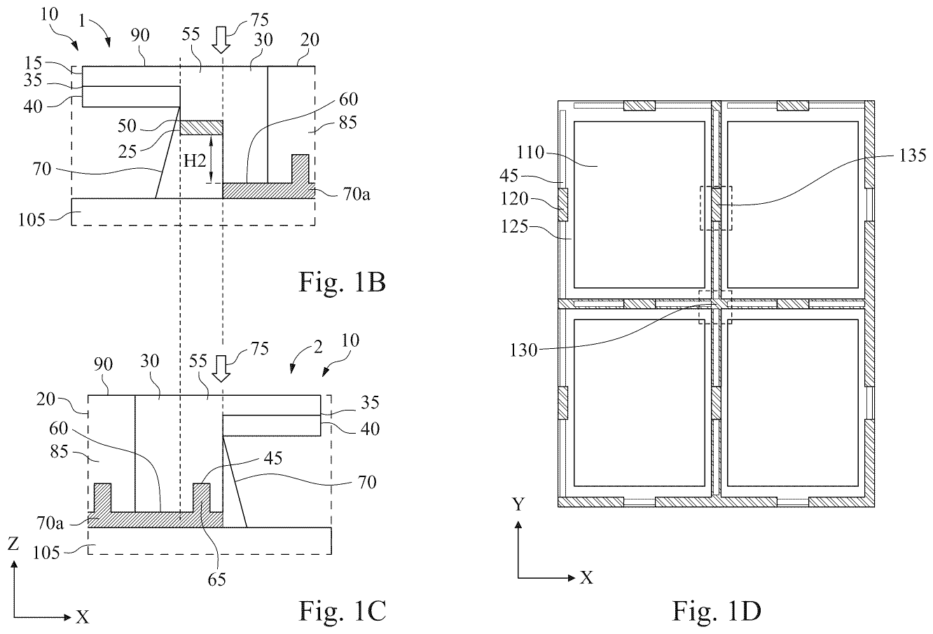

FIG. 1A shows a plan view of a nanoimprint lithography mask 10 according to embodiments of the present disclosure. In some embodiments, the mask 10 includes a pattern region (or device region) 20 including a pattern corresponding to features formed on a device. In some embodiments, the pattern corresponds to features of a semiconductor device. In some embodiments, the patterns correspond to an integrated circuit. The patterned region is surrounded by a frame region 30. In some embodiments, the frame region 30 is rectangular shape, and has a width W1 ranging from about 13 mm to about 152 mm, and a height H1 ranging from about 15 mm to about 152 mm. In some embodiments, the frame width W1 ranges from about 20 mm to about 76 mm, and the frame height H1 ranges from about 25 mm to about 96 mm. In some embodiments, the frame width W1 is about 26 mm and the height H1 is about 33 mm.

The frame region 30 includes portions where an alignment mark pattern 45 is formed and portions where an ultraviolet radiation absorption layer 25 is formed. In some embodiments, the alignment mark pattern 45 is a trench. In some embodiments, the light absorption layer 25 is tunable. The amount of ultraviolet radiation absorbed by the light absorption layer 25 can be designed to allow some ultraviolet radiation to pass through the light absorption layer 25 or to completely absorb ultraviolet radiation. In some embodiments, a light absorption layer 25 on one side of the frame has a corresponding alignment mark pattern 45 on an opposing side of the frame. Likewise, in some embodiments, an alignment mark pattern 45 on one side of the frame has a corresponding light absorption layer 25 on an opposing side of the frame as shown in FIG. 1A.

A peripheral region 15 surrounds the frame region in some embodiments. The peripheral region 15 includes a light blocking layer 40 disposed thereon in some embodiments.

FIGS. 1B and 1C are detailed cross-sectional views of the nanoimprint lithography mask contacting a resist layer according to embodiments of the present disclosure. FIG. 1B shows area 1 of the mask 10 contacting the resist layer 70, 70a disposed over a substrate 105. FIG. 1C shows area 2 of the mask 10 contacting the resist layer 70, 70a. The resist layer 70, 70a is exposed to ultraviolet radiation 75 through the mask 10. The ultraviolet radiation 75 cures or hardens the resist layer 70. The ultraviolet radiation 75 does not impinge on the uncured regions 70 of the resist layer, while the regions 70a that are exposed to the ultraviolet radiation 75 are cured or hardened. The light blocking layer 40 and the light absorption layer prevent the outermost portions of the resist layer 70 from being exposed to the ultraviolet radiation 75.

As shown in FIGS. 1B and 1C, the peripheral region 15 and the frame region 30 of the mask are stepped. The peripheral region 15 is mesa-shaped. The peripheral region has a mesa surface at a first level 35 located at a first distance from a substantially planar main surface 90. The light absorption layer 25 is formed at a second level 50 located at a second distance from the substantially planar main surface 90. The second level 50 is further away from the main surface 90 than the first level 35. A pattern is formed in a main surface of the pattern region 20. The main surface of the pattern region is formed at a third level 60 located at a third distance from the substantially planar main surface 90. The third level 60 is further away from the main surface 90 than the second level 50. As shown in FIGS. 1B and 1C, on one side of the mask 10, there are three levels (steps) and the light absorption layer 25 is formed at the middle level (step), while on an opposing side there are two levels (steps) and no light absorption layer is formed, but the mask includes an alignment mark pattern 45, where an alignment mark 65 is formed in the cured resist layer 75.

During a substrate patterning operation, the mask 10 is formed to form a first pattern in a portion of the resist layer 70, and then the masked is lifted from the resist layer 70, laterally moved, and then pressed into an adjacent portion of the resist to form a second pattern in the adjacent portion of the resist. This process is repeated until a desired number of the same patterns are formed in the resist layer. To maximize device yield and make the efficient use of the substrate, portions of the resist layer overlap below the frame region 30 mask when forming adjacent pattern fields, as shown in FIGS. 1B, 1C, and 1D. The overlapping regions 55 correspond to the frame region 30, are shown in FIGS. 1B and 1C. For example, during a first pattern formation operation in a first pattern field, in the left side of the mask the resist layer 70 below the frame region 30 is not exposed to the ultraviolet radiation 75 because of the radiation is absorbed by the light absorption layer, while on the right side of the mask an alignment mark 45 is formed in the frame region 30. When the mask 10 is removed from the resist layer and moved laterally to the right (or the substrate 105 is moved laterally to the left) the alignment mark 45 will be positioned in the overlapping region 55 below the light absorption layer 25. The light absorption layer 25 is spaced a sufficient distance H2 from the third level 60 of the mask 10, so that the mask 10 does not contact the alignment mark 45 during subsequent processing. Thus, possible damage to the mask 10 and/or the alignment mark 45 is avoided because the mask 10 and the alignment mark will not collide.

The mask 10 includes an ultraviolet transmissive substrate 85 material, such as a glass or a silicone. In some embodiments, the glass is made of a fused silica and the silicone is a polydimethylsiloxane.

The pattern in the pattern region 20 is formed by a suitable electron beam mask writing operation, ion beam mask writing operation, or photolithographic operation, such as extreme ultraviolet (EUV) lithography in some embodiments. The steps 35, 50 are formed in the peripheral region 15 and frame region 30 by using suitable photolithographic and etching operations of the light transmissive substrate 85.

In some embodiments, a light blocking layer 40 made of a light blocking material disposed over the mesa formed in the light transmissive substrate 85 at a first level 35. In embodiments of the present disclosure, the light blocking or opaque material includes a Cr-based material, such as Cr, CrO, CrON, CrB, and/or CrBN. In some embodiments where nitrogen is present in the Cr-based material a nitrogen content of the Cr-based material is about 16 atomic % to about 40 atomic %, and in some embodiments where oxygen is present in the Cr-based material an oxygen content of the Cr based material is more than 0 atomic to about 30 atomic %. In some embodiments, the light blocking layer 40 has a multilayered structure of Cr, CrO, CrON, CrB, and/or CrBN. In some embodiments, the thickness of the light blocking layer 25 is in a range from about 20 nm to about 100 nm, is in a range from about 25 nm to about 75 nm in other embodiments, is in a range from about 35 nm to about 50 nm in other embodiments, and is in a range of about 40 nm to about 46 nm in yet other embodiments. In some embodiments, when the Cr-based material includes oxygen, the amount of the oxygen is in a range from about 5 atomic % to about 30 atomic %, and is in a range from about 10 atomic % to about 25 atomic % in other embodiments. In some embodiments, the light blocking layer 40 further includes one or more elements of Co, Te, Hf and/or Ni.

In some embodiments, the light blocking layer 40 is made of TaN, TaO, TaB, TaBO, or TaBN. In other embodiments, the light blocking layer 40 includes an Ir-based material including elemental iridium (not compound) or an iridium alloy, such as IrPt, IrAl, IrRu, IrB, IrN, IrSi, and/or IrTi. In other embodiments, the light blocking layer 40 includes a Pt-based material including elemental platinum (not compound) or a Pt alloy, such as PtAl, PtRu, PtB, PtSi, PtN, and/or PtTi. In other embodiments, the light blocking layer 40 includes a Co-based material including elemental cobalt (not compound) or a Co alloy, such as CoO, CoB, CoBN, CON, and/or CoSi.

In some embodiments, the light blocking layer 40 is formed by chemical vapor deposition, plasma-enhanced chemical vapor deposition, atomic layer deposition, physical vapor deposition, or any other suitable film forming method.

In some embodiments, the light blocking layer further includes one or more elements, such as Si, B, Ge, Al, As, Sb, Te, Se and/or Bi.

In some embodiments, a light absorption layer 25 made of a light absorbing material disposed at the second level 50 formed in the light transmissive substrate 85. In embodiments of the present disclosure, the light absorption layer 25 includes a suitable organic or inorganic material. In some embodiments, light absorption material is one or more organic materials selected from the group consisting of benzophenones, benzotriazoles, cyanoacrylates, hydroxybenzophenones, hydroxyphenyl benozotriazoles, oxanilides, and hydroxyphenyl triazines. In some embodiments, light absorbing material is made up of one or more carbon-based materials, including carbon black, graphite, and carbon nanotubes. In some embodiments, the light absorption material includes one or more inorganic materials selected from the group consisting of a titanium oxide; a zinc oxide; a Cr-based material, such as Cr, CrO, CrON, CrB, and/or CrBN; a Ta-based material including elemental Ta (not compound) or a Ta alloy, such as TaN, TaO, TaB, TaBO, and/or TaBN; an Ir-based material including elemental iridium (not compound) or an iridium alloy, such as IrPt, IrAl, IrRu, IrB, IrN, IrSi, and/or IrTi; a Pt-based material including elemental platinum (not compound) or a Pt alloy, such as PtAl, PtRu, PtB, PtSi, PtN, and/or PtTi; and a Co-based material including elemental cobalt (not compound) or a Co alloy, such as CoO, CoB, CoBN, CON, and/or CoSi.

In some embodiments, the light absorption layer 25 is formed by chemical vapor deposition, plasma-enhanced chemical vapor deposition, atomic layer deposition, physical vapor deposition, or any other suitable film forming method.

In some embodiments, the light absorption layer further includes one or more elements, such as Si, B, Ge, Al, As, Sb, Te, Se and/or Bi.

The light absorption layer can be tuned to absorb different amounts of ultraviolet radiation by appropriate selection of the thickness of the light absorption layer, the width of the light absorption layer, and light absorbing material. In some embodiments, the light absorption layer 25 is tuned to allow some ultraviolet light pass through the light absorption layer thereby partially curing the resist layer.

In some embodiments, the thickness of the light absorption layer 25 is in a range from about 1 nm to about 50 nm, is in a range from about 5 nm to about 25 nm in other embodiments, and is in a range from about 10 nm to about 20 nm in other embodiments.

FIG. 1D shows a plan view of a portion of a substrate with multiple overlapping pattern (or device) fields formed thereon. As shown in FIG. 1D, a plurality of rectangular pattern fields 110 are formed over a substrate using nanoimprint lithography masks 10 and patterning techniques disclosed herein. A border 125 corresponding to the frame region 30 of the mask 10 is formed around each of the pattern fields 110. An alignment mark 45 is formed surrounding pattern fields in some embodiments, except at portions 120 corresponding to the light absorption layer 25 on the mask 10. In some corner areas between adjacent pattern fields a corner overlap 130 corresponding to an overlap of the mask light absorption layers 25 is formed in some embodiments. In some embodiments, edge overlap areas 135 are formed corresponding to an overlap of the mask light absorption layers 25.

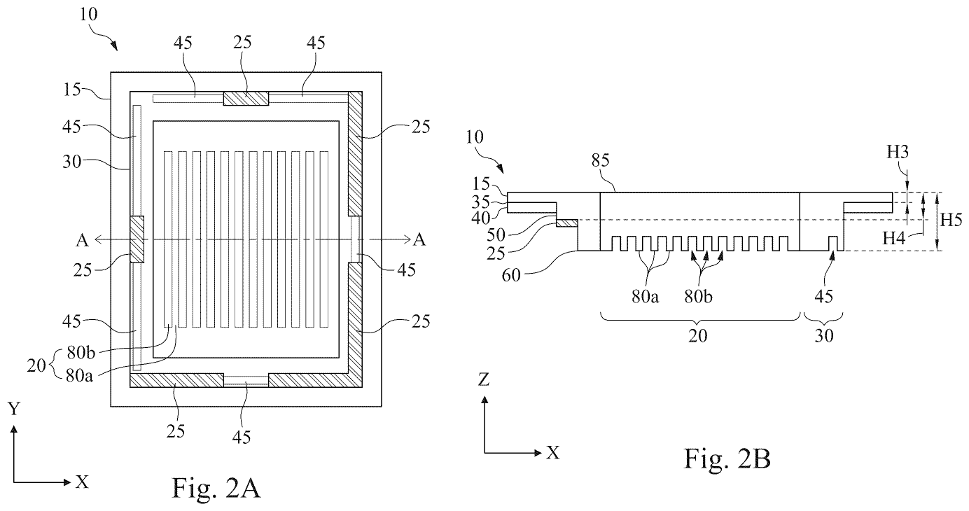

FIGS. 2A and 2B show a plan view and cross-sectional view, respectively, of a nanoimprint lithography mask according to embodiments of the present disclosure. FIG. 2A shows a nanoimprint lithography mask 10, wherein the pattern region 20 includes a pattern 80a, 80b. In the embodiment shown, the pattern includes a plurality alternating projections 80a and recesses 80b. Although a plurality of parallel lines are illustrated in the pattern region 20 in FIGS. 2A and 2B, the present disclosure is not limited to such patterns. Any pattern can be formed in the pattern region.

FIG. 2B illustrates a cross-sectional view of the mask taken along line A-A. As shown, the cross-sectional line passes through the light absorption layer 25 in the frame region 30 on one side of the pattern region 20 and the alignment mark 45 in the frame region 30 on an opposing side of the pattern region 20. The thickness H5 of the mask 10 along the Z-direction perpendicular to the planar main surface 90 is sufficient to maintain structural integrity of the mask during the semiconductor device manufacturing operations. In some embodiments, the thickness H5 of the mask ranges from about 3 mm to about 40 mm, and from about 6 mm to about 25 mm in other embodiments. The thickness H5 corresponds to distance between the third level 60 and the planar main surface 90. In some embodiments the thickness H3 of the peripheral region 15 from the first level 35 to the planar main surface 90 ranges from about 0.3 mm to about 10 mm, and from about 1 mm to about 5 mm in other embodiments. In some embodiments, the thickness H4 of the mask 100 from the planar main surface 90 to the second level ranges from about 2 mm to about 25 mm, and from about 4 mm to about 17 mm in other embodiments. In some embodiments a ratio H4/H5 ranges from about 0.05 to about 0.67, and in other embodiments, the ratio H4/H5 ranges from about 0.2 to about 0.5. In some embodiments, the ratio H3/H5 ranges from about 0.01 to about 0.3, and in other embodiments, the ratio H3/H5 ranges from about 0.05 to about 0.2.

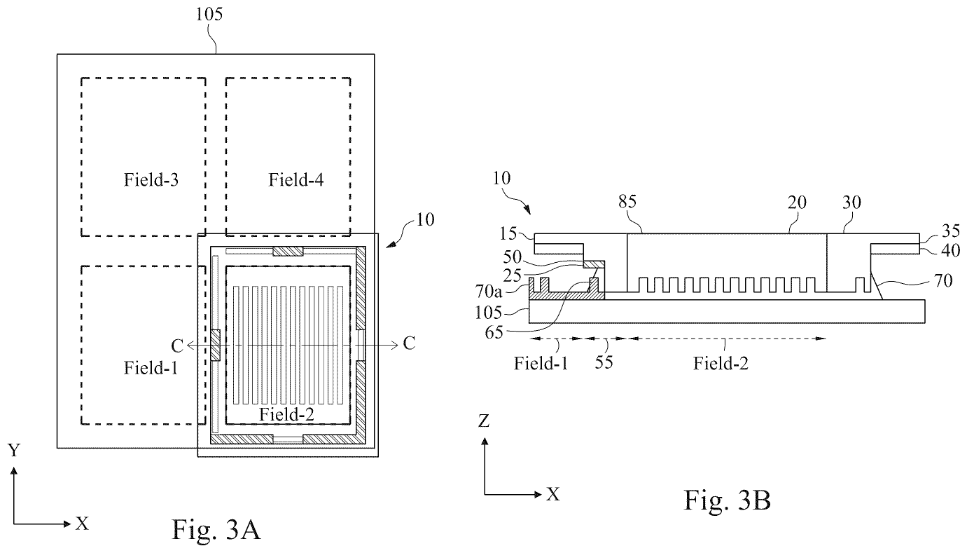

FIGS. 3A and 3B show a plan view and cross-sectional view, respectively, of a semiconductor device manufacturing operation using a nanoimprint lithography mask according to embodiments of the present disclosure. FIG. 3A shows the mask 10 positioned over a pattern field of the substrate 105. FIG. 3B shows a cross-sectional view seen along line C-C of FIG. 3A.

The substrate 105 is a semiconductor substrate, such as a wafer, or other suitable substrate to be patterned to form an integrated circuit thereon is provided. In some embodiments, the semiconductor substrate includes silicon. Alternatively or additionally, the semiconductor substrate includes germanium, silicon germanium, or other suitable Group IV or Group III-V semiconductor materials. The substrate 105 includes a single crystalline semiconductor layer on at least it surface portion, according to some embodiments. The substrate 105 may include a single crystalline semiconductor material such as, but not limited to Si, Ge, SiGe, GaAs, InSb, GaP, GaSb, InAlAs, InGaAs, GaSbP, GaAsSb, and InP. In some embodiments, the substrate 10 is a silicon layer of an SOI (silicon-on insulator) substrate. In certain embodiments, the substrate 105 is made of crystalline Si.

The substrate 105 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 105. The germanium concentration of the SiGe buffer layers may increase from 30 atomic % for the bottom-most buffer layer to 70 atomic % for the top-most buffer layer.

In some embodiments, the substrate 105 includes one or more layers of at least one metal, metal alloy, and metal nitride/sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 105 includes a dielectric material having at least a silicon or metal oxide or nitride of the formula MX_{b}, where M is a metal or Si, X is N or O, and b ranges from about 0.4 to about 2.5. In some embodiments, the substrate 105 includes silicon dioxide, silicon nitride, aluminum oxide, hafnium oxide, lanthanum oxide, and combinations thereof.

In the embodiment shown in FIGS. 3A and 3B, the mask 10 is shown overlying pattern field 2 of the semiconductor substrate, after the mask 10 was used to form the cured, patterned resist layer 70a in pattern field 1. As shown in FIG. 3B, the resist layer 70a in pattern field 1 is cured because it has already been exposed to ultraviolet radiation, while the resist layer 70 in pattern field 2 is not cured because it has not been exposed to ultraviolet radiation. As shown in FIG. 3B, there is sufficient clearance between the alignment mark 65 and the light absorption layer 25 of the mask in the overlapping region 55. The uncured resist material in the overlapping region 55 will not be cured by the subsequent ultraviolet radiation exposure of pattern field 2 because the radiation will be blocked by the light absorption layer 25. The uncured resist material 70 can be subsequently removed by a suitable air flushing operation, or by applying a suitable solvent to the mask 10.

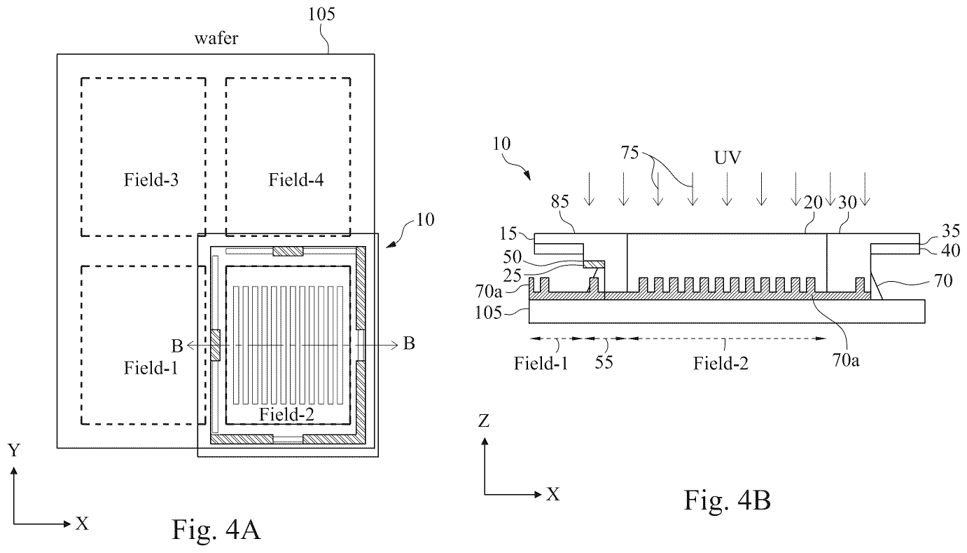

FIGS. 4A and 4B show a plan view and cross-sectional view, respectively, of a semiconductor device manufacturing operation using a nanoimprint lithography mask according to embodiments of the present disclosure. FIG. 4B is a cross-section seen along line B-B of FIG. 4A. As shown in FIG. 4B, ultraviolet radiation 75 from an ultraviolet radiation source passes through the ultraviolet transmissive portions of the mask 10 exposing the resist layer to form the cured resist layer 70a, thereby transferring the pattern in the pattern region 20 of the mask 10 to the resist layer 70a. Portions of the resist layer 70 in the overlapping region 55 are not cured, and can be subsequently removed after the ultraviolet radiation exposure operation using a suitable air flushing or solvent removal operation.

In some embodiments, the ultraviolet radiation source (not shown) includes a mercury vapor lamp; halogen lamps; gas discharge lamps, including argon and deuterium arc lamps, mercury-xenon arc lamps, and metal-halide arc lamps; ultraviolet light emitting diodes; and excimer lasers, including KrF and ArF lasers.

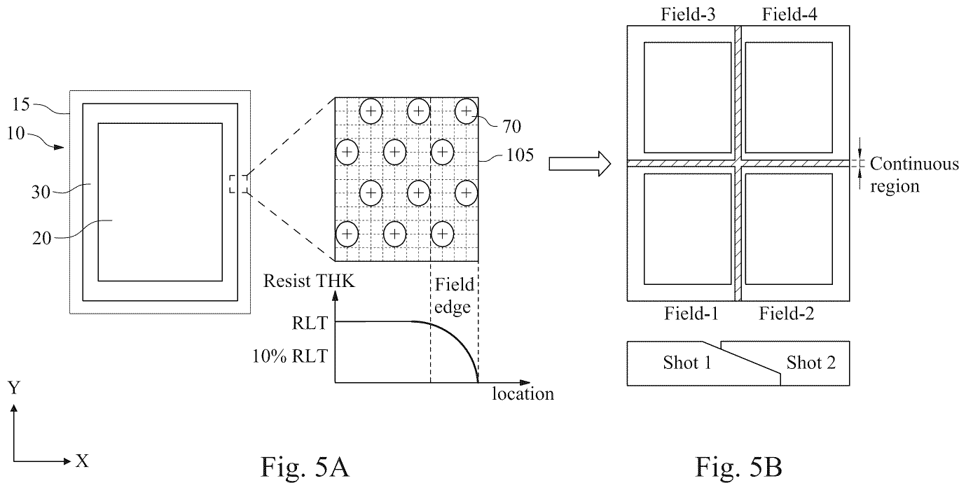

FIG. 5A shows a plan view of a nanoimprint lithography mask and a portion of a substrate with a resist layer 70 on a substrate 105 corresponding to a frame region 30 of the mask, and a graph showing the resist layer thickness at the field edge of the substrate according to embodiments of the present disclosure. As shown in the graph, at the frame region the resist layer thickness (RLT) falls to about zero at the edge of the field when using a nanoimprint lithography mask 10 and nanoimprint lithography patterning methods according to embodiments of the present disclosure. In other nanoimprint lithography techniques, an extruded resist hump would be formed at the frame edge. Thus, a gap would have to be included between the pattern fields on the semiconductor substrate to accommodate the extruded resist hump in other nanoimprint lithography techniques.

FIG. 5B shows a plan view of a patterned region of a substrate illustrating shot overlapping according to some embodiments of the present disclosure. In some embodiments, the overlapping shots provided by masks and stamps and the nanoimprint lithography techniques of the present disclosure allow the formation of a continuous region between fields, rather than a gap between pattern fields that would be necessary in other nanoimprint lithography techniques. Thus, the masks and nanoimprint lithography techniques of the present disclosure can provide more efficient use of the substrate patterning area.

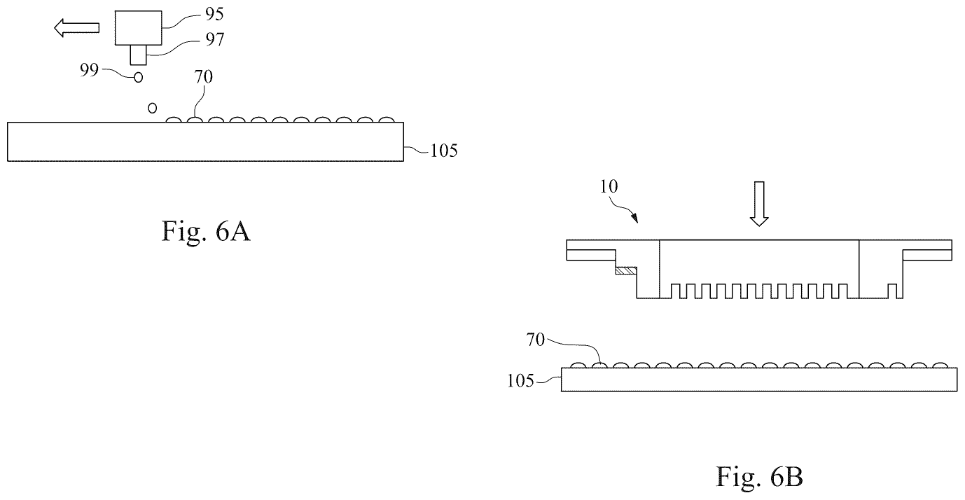

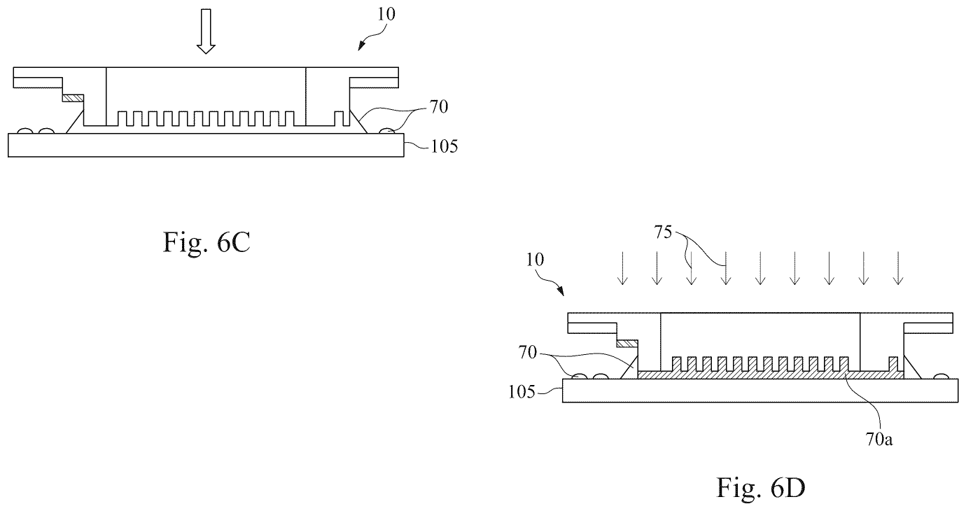

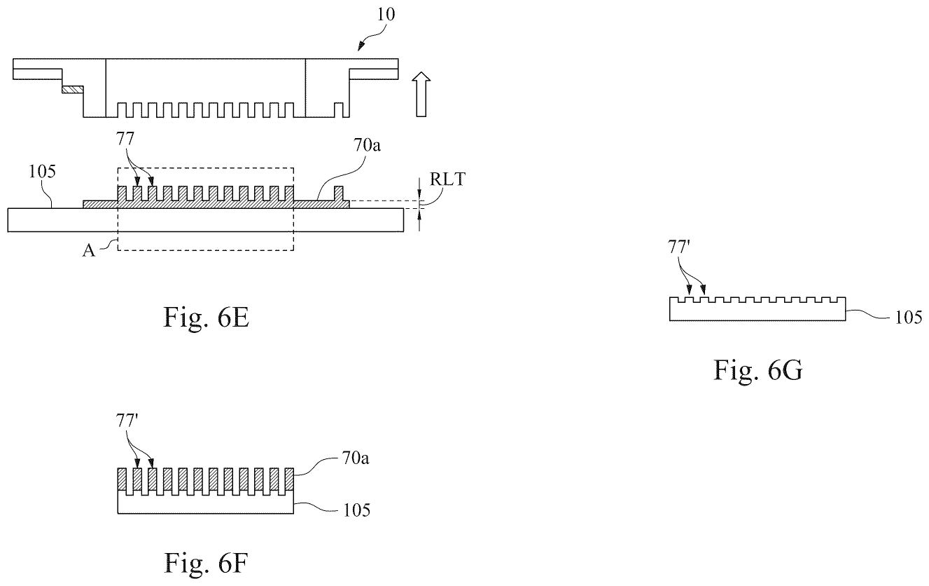

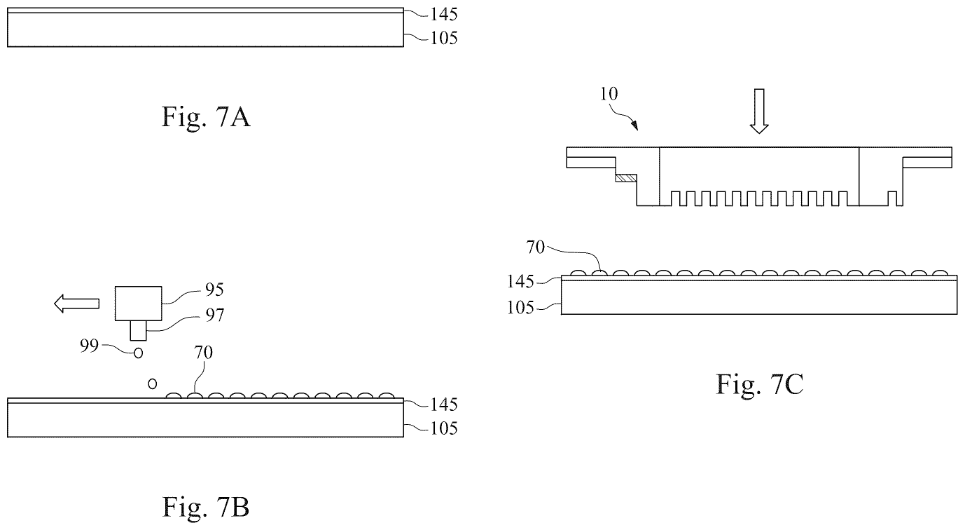

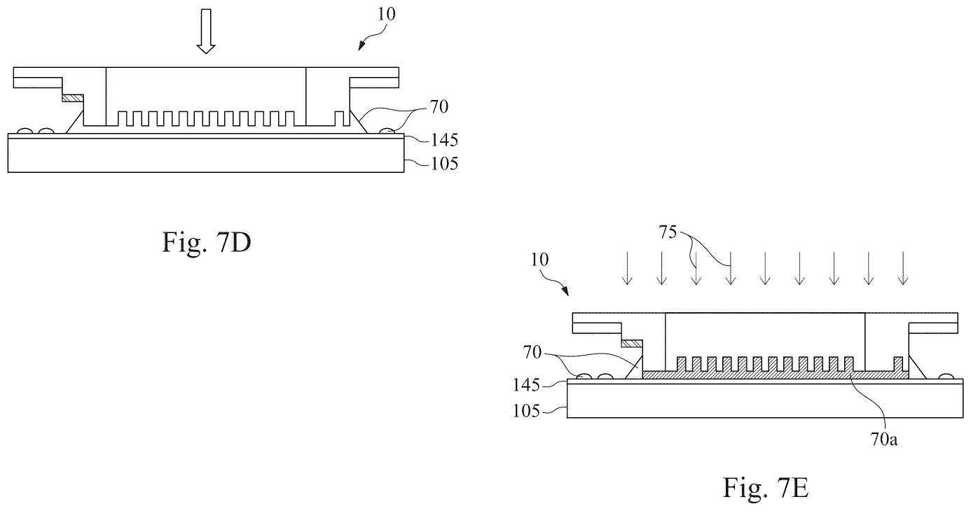

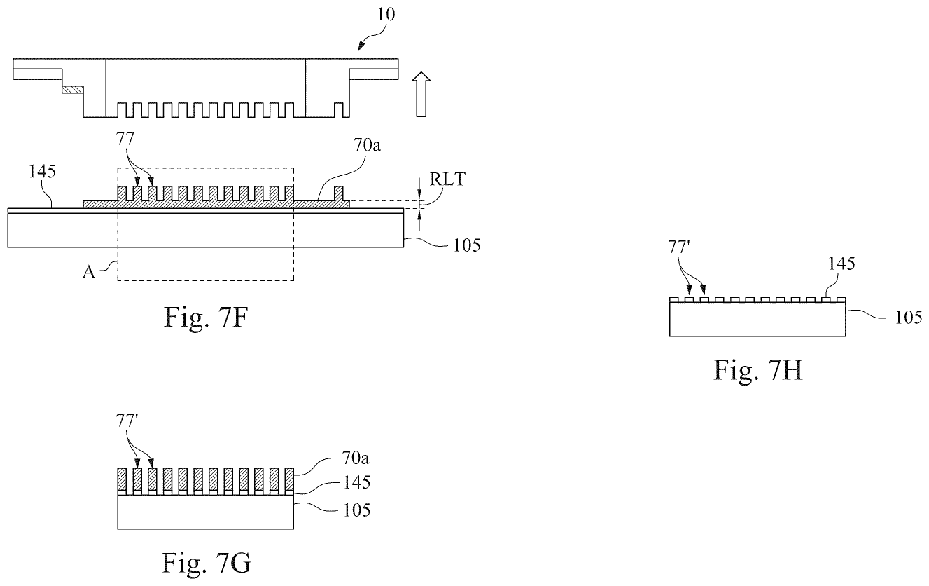

The nanoimprint lithography methods according to embodiments of the disclosure will be discussed in further detail in reference to FIGS. 6A-7H. FIGS. 6A-6G schematically illustrate sequential operations of manufacturing a semiconductor device according to embodiments of the disclosure.

A resist material is deposited over a substrate 105 to form a resist layer 70. In some embodiments, the resist layer is deposited using an inkjet printer 95, as shown in FIG. 6A. The inkjet 95 dispenses droplets 99 of resist material from an inkjet head. The inkjet head may include a plurality of nozzles 97 that simultaneously dispenses a plurality of resist material droplets. In some embodiments, the inkjet head may include hundreds of nozzles 97. In some embodiments, the inject 95 moves laterally relative to the substrate 105 while depositing resist material droplets 99 over the surface of the substrate 105. In some embodiments, the inkjet 95 and the substrate are appropriately sized so that an entire pattern field is deposited simultaneously. In some embodiments, the resist droplet volumes range from about 0.1 pL to about 100 μL, in other embodiments the droplet volume ranges from about 1 pL to about 10 μL, and other embodiments, the droplet volume ranges from about 1 nL to about 1 μL. The resist layer 70 can be formed by other suitable techniques in other embodiments, such as by a spin coating operation.

The resist material includes polymerizable monomers or oligomers in some embodiments that polymerize when exposed to ultraviolet radiation. In some embodiments, the resist material includes a photoactive component, including one or more of a photosensitizer, photoinitiator, and photoacid generator. In some embodiments, polymerizable monomer includes acrylates, methacrylates, epoxies, vinyl ethers, and thiols and alkenes.

The resist material composition includes a solvent in some embodiments. The solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK). In some embodiments, the resist-coated substrate is heated after depositing the resist layer to drive off the solvent.

A shown in FIG. 6B, a mask 10 according to embodiments of the present disclosure is positioned over the resist-coated substrate 105. Then, as shown in FIG. 6C, the mask is pressed into the resist layer 70. The pressure causes the resist droplets on the surface of the substrate 105 to spread and merge. The recesses in the mask 10 are filled with the resist material by capillary action. A portion of the resist material spreads up the sidewall of the mask outside the frame region by capillary action in some embodiments.

Next, as shown in FIG. 6D, the resist layer 70 is exposed to ultraviolet radiation 75 through the mask 10, and the exposed resist layer is cured or hardened. During the ultraviolet radiation exposure, the resist material in the exposed portions of the resist layer 70a polymerize and/or crosslink. The portions of the resist layer 70 that are shielded by the light blocking layer 40 or the light absorption layer 25 are not cured.

The mask 10 is subsequently removed from the resist-coated substrate leaving the patterned resist layer 70a including pattern 77 on the substrate 105, as shown in FIG. 6E. In some embodiments, the surface of the pattern in the pattern region 20 of the mask is coated with an anti-stick agent to prevent the resist layer from sticking to the mask. The surface of the mask or stamp 10 does not contact the substrate 105 during the patterning operations in some embodiments. Therefore, portions of the resist layer between the third level 60 of the mask 10 and the substrate 105 are also cured during the ultraviolet radiation exposure operation resulting in a residual layer thickness (RLT) of the cured resist layer 70a over the substrate 105. The thickness of the RLT can be adjusted by controlling various resist and pattern forming parameters including resist material, resist viscosity, type of solvent in the resist material, solvent concentration in the resist material, and stamping pressure. In some embodiments, the RLT has a thickness of about 0.1 nm to about 10 nm. In some embodiments, the RLT has a thickness of about 1 nm. While it may be desirable to minimize the thickness of the RLT, completely eliminating the RLT may not be desirable, because directly contacting the mask 10 to the substrate 105 may damage the mask or substrate.

After the mask or stamp 10 is removed from the resist material, the uncured resist material is removed from the surface of the substrate and/or mask by use of a suitable air flushing technique or by a solvent.

In some embodiments, the RLT is subsequently removed by a suitable dry etching technique, such as plasma etching or reactive ion etching, as shown in FIG. 6F. Through etching, the resist pattern 77 is extended through the RLT and into the substrate 105 forming a pattern 77′ in the substrate. In some embodiments, the etch chemistry and etching parameters are adjusted during the etching operation depending on the material being etched (i.e.—cured resist material or substrate). In some embodiments, the resist pattern is then subsequently removed from the patterned substrate 105 using a suitable resist stripping or plasma ashing operation, as shown in FIG. 6G.

FIGS. 7A-7G schematically illustrate sequential operations of manufacturing a semiconductor device according to embodiments of the disclosure. The process of FIGS. 7A-7G is similar to that disclosed in reference to FIGS. 6A-6G, with the addition of a target layer 145 to be patterned disposed over the substrate 105, as shown in FIG. 7A. In some embodiments, the target layer 145 includes a conductive layer, such as a metallic layer or a polysilicon layer, a dielectric layer, such as silicon oxide, silicon nitride, SiON, SiOC, SiOCN, SiCN, hafnium oxide, or aluminum oxide, or a semiconductor layer, such as an epitaxially formed semiconductor layer. In some embodiments, the target layer 145 is formed over an underlying structure, such as isolation structures, transistors, or wirings.

A resist material is deposited over the target layer 145 to form a resist layer 70. In some embodiments, the resist layer is deposited using an inkjet printer 95, as shown in FIG. 7B, and disclosed herein in reference to FIG. 6A. The resist layer 70 is formed by other suitable techniques in other embodiments, such as by a spin coating operation.

A shown in FIG. 7C, a mask 10 according to embodiments of the present disclosure is positioned over the resist-coated target layer 145. Then, as shown in FIG. 7D, the mask is pressed into the resist layer 70. The pressure causes the resist droplets on the surface of the target layer 145 to spread and merge. The recesses in the mask 10 are filled with the resist material by capillary action. A portion of the resist material spreads up the sidewall of the mask outside the frame region by capillary action in some embodiments.

Next, as shown in FIG. 7E, the resist layer 70 is exposed to ultraviolet radiation 75 through the mask 10, and the exposed resist layer is cured or hardened. During the ultraviolet radiation exposure, the resist material in the exposed portions of the resist layer 70a polymerize and/or crosslink. The portions of the resist layer 70 that are shielded by the light blocking layer 40 or the light absorption layer 25 are not cured.

The mask 10 is subsequently removed from the resist-coated target layer 145 leaving the patterned resist layer 70a including pattern 77 on the substrate 105, as shown in FIG. 7F. In some embodiments, the surface of the pattern in the pattern region 20 of the mask is coated with an anti-stick agent to prevent the resist layer from sticking to the mask. The surface of the mask or stamp 10 does not contact the target layer 105 during the patterning operations in some embodiments. Therefore, portions of the resist layer between the third level 60 of the mask 10 are also cured during the ultraviolet radiation exposure operation resulting in a residual layer thickness (RLT) of the cured resist layer 70a over the target layer 145. The thickness of the RLT can be adjusted by controlling various resist and pattern forming parameters including resist material, resist viscosity, type of solvent in the resist material, solvent concentration in the resist material, and stamping pressure. While it may be desirable to minimize the thickness of the RLT, completely eliminating the RLT may not be desirable, because directly contacting the mask 10 to the target layer 145 may damage the mask or substrate.

In some embodiments, the RLT is subsequently removed by a suitable dry etching technique, such as plasma etching or reactive ion etching, as shown in FIG. 7G. The resist pattern 77 is extended through the RLT and into the target layer 145 forming a pattern 77′ in the target layer. In some embodiments, the etch chemistry and etching parameters are adjusted during the etching operation depending on the material being etched (i.e.—cured resist material or target layer).

In some embodiments, the resist pattern is then subsequently removed from the patterned target layer using a suitable resist stripping or plasma ashing operation, as shown in FIG. 7H.

After the mask or stamp 10 is removed from the resist material, the uncured resist material is removed from the surface of the target layer and/or mask by use of a suitable air flushing technique or by a solvent, in some embodiments.

Additional operations may be performed on the structure of FIGS. 6G and 7H, including forming transistors, including fin field effect transistors (FinFETs), gate-all-around field effect transistors (GAA FETs), bipolar transistors, and planar transistors; memory devices; capacitors; insulating layers; and metal wiring layers, including interconnects and vias. The structures of FIGS. 6G and 7H may be part of a larger integrated circuit, including additional devices and components.

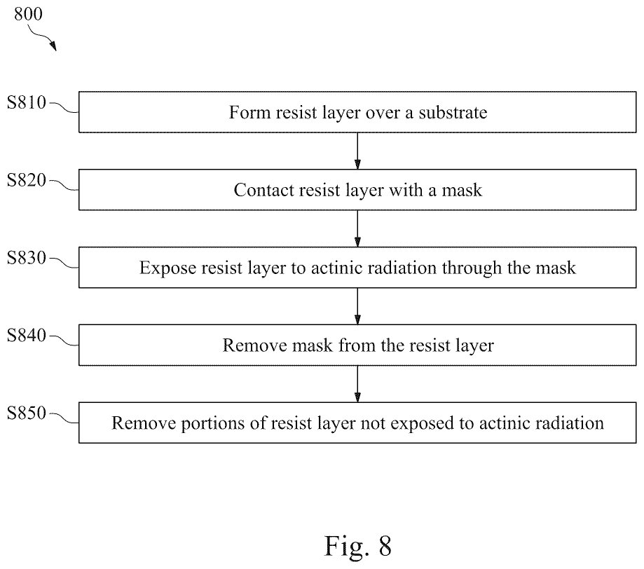

A method 800 of manufacturing a semiconductor device according to an embodiment of the disclosure is illustrated in the flowchart of FIG. 8. The method 800 includes forming a resist layer 70 over a substrate 105 in operation S810, as shown in FIG. 6B. In some embodiments, the substrate 105 is a semiconductor substrate. In operation S820, a mask 10 is contacted with the resist layer 70. The mask 10 can be any of the nanoimprint lithography masks disclosed herein. The mask is pressed into the resist layer 70 so that resist layer material fills the recesses in the mask pattern, as shown in FIG. 6C. Then, in operation S830, the resist layer is cured or hardened by exposing the resist layer to actinic radiation through the mask, as shown in FIG. 6D. The mask 10 is subsequently removed from the cured resist layer 70a in operation S840, and in operation S850, portions of the resist layer 70 not exposed to the actinic radiation are removed as shown in FIG. 6E. In some embodiments, the portions of the resist layer not exposed to actinic radiation are removed by a suitable air flushing operation. In other embodiments, the portions of the resist layer not exposed to actinic radiation are removed by a suitable solvent.

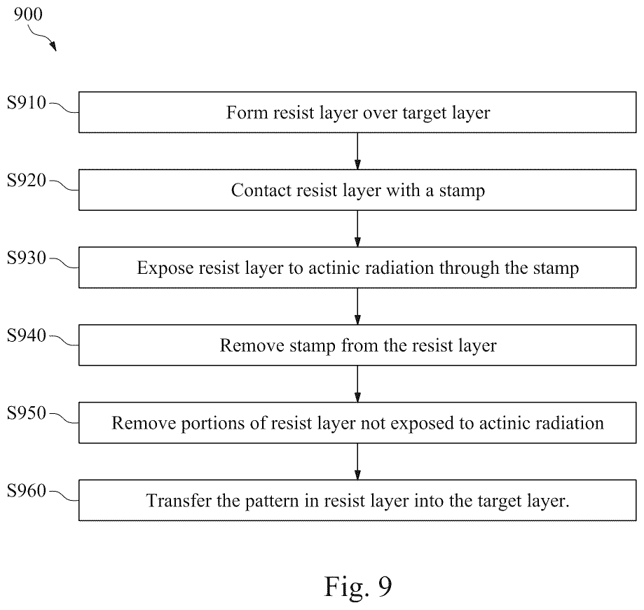

Another method 900 of manufacturing a semiconductor device according to an embodiment of the disclosure is illustrated in the flowchart of FIG. 9. The method 900 includes forming a resist layer 70 over a target layer 145 in operation S910, as shown in FIG. 7B. In some embodiments, the target layer 145 can be any of the target layers disclosed herein, and the target layer 145 is formed over a semiconductor substrate or one or more layers of semiconductor active or passive devices or wiring layer disposed over the semiconductor substrate. In operation S920, the resist layer 70 is contacted with a stamp 10 having a pattern formed thereon. The stamp 10 can be any of the nanoimprint lithography stamps disclosed herein. The stamp 10 is pressed into the resist layer 70 so that resist layer material fills the recesses in the pattern formed in the stamp, as shown in FIG. 7D. Then, in operation S930, the resist layer is cured or hardened by exposing the resist layer to actinic radiation through the stamp, as shown in FIG. 7E. The stamp 10 is subsequently removed from the cured resist layer 70a in operation S940 leaving a patterned resist layer 77 disposed on the target layer 145, and in operation S950, portions of the resist layer 70 not exposed to the actinic radiation are removed as shown in FIG. 7F. In some embodiments, the portions of the resist layer not exposed to actinic radiation are removed by a suitable air flushing operation. In other embodiments, the portions of the resist layer not exposed to actinic radiation are removed by a suitable solvent. The pattern 77 formed in the resist layer is subsequently transferred into the target layer 145 in operation S960, and as shown in FIG. 7G.

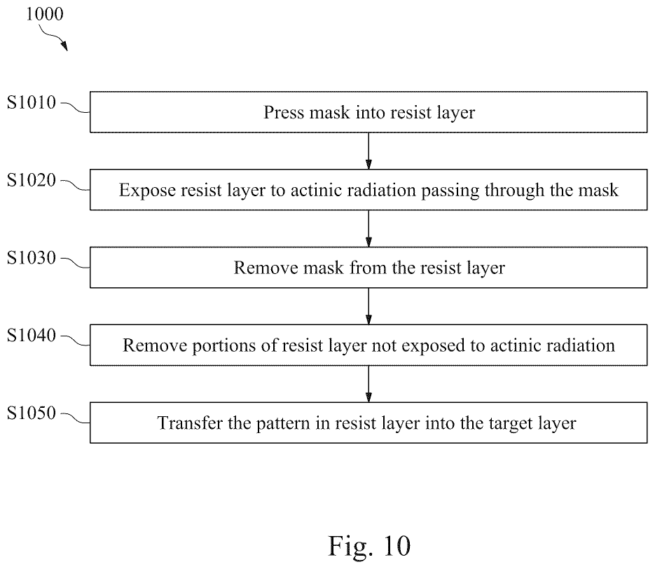

Another method 1000 of manufacturing a semiconductor device according to an embodiment of the disclosure is illustrated in the flowchart of FIG. 10. The method 1000 includes pressing a mask 10 into a resist layer 70 disposed over a substrate 105 in operation S1010, as shown in FIGS. 6C and 6D. In some embodiments, the substrate 105 is a semiconductor substrate or the substrate includes a target layer 145 disposed over a semiconductor substrate. The mask 10 can be any of the nanoimprint lithography masks disclosed herein. The pressing the mask into the resist layer causes the resist material to flow and fill recesses in the pattern formed in the mask. In operation S1020, the resist layer is exposed to actinic radiation passing through the mask to cure or harden the resist layer, as shown in FIG. 6D. The mask 10 is subsequently removed from the cured resist layer 70a in operation S1030, and in operation S1040, portions of the resist layer 70 not exposed to the actinic radiation are removed as shown in FIG. 6E. In some embodiments, the portions of the resist layer not exposed to actinic radiation are removed by a suitable air flushing operation. In other embodiments, the portions of the resist layer not exposed to actinic radiation are removed by a suitable solvent. In some embodiments, the pattern 77 formed in the resist layer is transferred into the substrate in operation S1050, and as shown in FIG. 6F. In some embodiments, a target layer 145 is formed between the resist layer 90 and the substrate 105, and the pattern 77 formed in the resist layer is transferred into the target layer 145 as shown in FIG. 7G.

Embodiments of the present disclosure include masks or stamps and techniques to prevent or suppress damage to nanoimprint lithography masks and alignment marks. Embodiments of the disclosure provide improved control of residual layer thickness variation at the pattern field edges. In addition, embodiments of the present disclosure enable more efficient use of the pattern fields of the substrate because gaps between pattern fields can be eliminated. Furthermore, uncured, residual resist can be easily removed from overlapped areas of the pattern fields.

It will be understood that not all advantages have been necessarily discussed herein, no particular advantage is required for all embodiments or examples, and other embodiments or examples may offer different advantages.

A method of manufacturing a semiconductor device according to an embodiment of the disclosure includes forming a resist layer over a substrate and contacting the resist layer with a mask. The mask includes: a device region having a device pattern, an overlapping region surrounding the device region and having a light absorption material, and a peripheral region surrounding the device region and the overlapping region, and having a light blocking material, wherein the light blocking material is at a first level, the light absorption material is at a second level, and the device pattern is at a third level, wherein the first, second, and third levels are at different positions. The resist layer is exposed to actinic radiation through the mask. The mask is removed from the resist layer, and portions of the resist layer not exposed to the actinic radiation are removed. In an embodiment, the actinic radiation is ultraviolet radiation. In an embodiment, the contacting the resist layer with the mask forms a pattern in the resist layer corresponding to the device pattern in the mask. In an embodiment, the exposing the resist layer to actinic radiation hardens exposed portions of the resist layer. In an embodiment, the portions of the resist layer not exposed to actinic radiation are removed by an air flushing operation. In an embodiment, the mask includes a substrate including a planar first main surface, the device region, the overlapping region, and the peripheral region. In an embodiment, the substrate has a second surface opposing the first main surface, and the device pattern is formed in the second surface. In an embodiment, the second level is closer to the first main surface than the third level. In an embodiment, the first level is closer to the first main surface than the second level.

Another embodiment of the disclosure includes a method of manufacturing a semiconductor device including forming a resist layer over a target layer. The resist layer is contacted with a stamp including a pattern including recesses and projections so that the resist layer fills the recesses in the stamp. The stamp includes: an ultraviolet light transmissive substrate having a first main surface, a second surface opposing the first main surface, a third surface opposing the first main surface, and a fourth surface opposing the first main surface, a first pattern region and a second pattern region in the second main surface, a light absorption layer disposed over the third surface, and an opaque layer disposed over the fourth surface. The fourth surface is closer to the first main surface than the third surface, and the third surface is closer to the first main surface than the second main surface. The resist layer is exposed to actinic radiation through the stamp thereby curing the resist layer exposed to the actinic radiation. The stamp is removed from the resist layer thereby providing a pattern in the resist layer disposed over the target layer. Portions of the resist layer not exposed to the actinic radiation are removed. In an embodiment, the resist layer comprises a plurality of resist droplets. In an embodiment, the resist droplets are formed by an inkjet operation. In an embodiment, the method includes transferring the pattern in the resist layer into the target layer. In an embodiment, the transferring the pattern includes an etching operation. In an embodiment, the ultraviolet light transmissive substrate includes a glass or a silicone.

Another embodiment according to the present disclosure is a method of manufacturing a semiconductor device including pressing a mask into a resist layer including a resist material disposed over a semiconductor substrate. The mask includes: an ultraviolet light transmissive substrate including a first main surface, an ultraviolet light blocking layer disposed over a peripheral region of the substrate on a second surface of the substrate opposing the first main surface a pattern region comprising a pattern formed in a third surface of the substrate opposing the first main surface, wherein the pattern region is surrounded by the peripheral region, and an ultraviolet light absorption layer disposed on the substrate between the peripheral region and the pattern region. The ultraviolet light blocking layer is at a first level relative to the first main surface, the ultraviolet light absorption layer is at a second level relative to the first main surface, and the pattern region is at a third level relative to the first main surface, and the first level, the second level, and the third level are at different distances from the first main surface. The pattern region includes a plurality of recesses and projections, and the recesses are filled with the resist material during the pressing the mask into the resist layer. The resist material is exposed to actinic radiation passing through the mask. The mask is removed from the resist layer thereby forming a pattern in the resist layer, and portions of the resist layer not exposed to the actinic radiation are removed. In an embodiment, the method includes transferring the pattern in the resist layer into the semiconductor substrate. In an embodiment, the second level is closer to the first main surface than the third level. In an embodiment, the ultraviolet light transmissive substrate is made of a glass or a silicone. In an embodiment, the ultraviolet light absorption layer is disposed on one side of the pattern region and not on an opposing side of the pattern region as seen in a cross-sectional view.

Another embodiment of the disclosure is a mask including a device region including a device pattern. An overlapping region surrounds the device region and has a light absorption material. A peripheral region surrounds the device region and the overlapping region, and has a light blocking material. The light blocking material is at a first level, the overlapping region is at a second level, and the device pattern is a third level. The first, second, and third levels are at different positions. In an embodiment, the mask includes a substrate including the device region, the overlapping region, and the peripheral region. In an embodiment, the substrate has a planar first main surface and a second surface opposing the first main surface, and the device pattern is formed in the second surface. In an embodiment, the second level is closer to the first main surface than the third level. In an embodiment, the first level is closer to the first main surface than the second level. In an embodiment, the substrate has a planar first main surface and a third surface opposing the first main surface, the light blocking material is formed over the third surface, and the first level is closer to the first main surface than the third level. In an embodiment, the substrate is made of a glass or a silicone. In an embodiment, the substrate is made of fused silica or a polydimethylsiloxane. In an embodiment, the light absorption material is an ultraviolet light absorbing material.

Another embodiment of the disclosure is a nanoimprint lithography mask, including an ultraviolet light transmissive substrate including a first main surface, a second surface opposing the first main surface, a third surface opposing the first main surface, and a fourth surface opposing the first main surface. A first pattern region and a second pattern region is in the second main surface. A light absorption layer is disposed over the third surface, and an opaque layer is disposed over the fourth surface. The fourth surface is closer to the first main surface than the third surface, and the third surface is closer to the first main surface than the second main surface. In an embodiment, the first pattern region includes a plurality of recesses and projections. In an embodiment, the first pattern region is rectangular-shaped in plan view and the second pattern region is disposed outside each side of the first pattern region in plan view. In an embodiment, the light absorption layer is disposed outside each side of the first pattern region in plan view. In an embodiment, the light absorption layer is disposed outside a first side of the first pattern region opposing the second pattern region disposed outside a second side of the first pattern region in plan view. In an embodiment, the opaque layer surrounds the first pattern region in plan view.

Another embodiment of the present disclosure is a nanoimprint lithography mask including an ultraviolet light transmissive substrate having a first main surface. An ultraviolet light blocking layer is disposed over a peripheral region of the substrate on a second surface of the substrate opposing the first main surface. A pattern region including a pattern is formed in a third surface of the substrate opposing the first main surface. The pattern region is surrounded by the peripheral region, and an ultraviolet light absorption layer is disposed on the substrate between the peripheral region and the pattern region. The ultraviolet light blocking layer is at a first level relative to the first main surface, the ultraviolet light absorption layer is at a second level relative to the first main surface, and the pattern region is at a third level relative to the first main surface, and the first level, the second level, and the third level are at different distances from the first main surface. In an embodiment, the second level is closer to the first main surface than the third level. In an embodiment, the substrate is made of a glass or a silicone. In an embodiment, the ultraviolet light blocking layer surrounds the pattern region in plan view. In an embodiment, the ultraviolet light absorption layer is disposed on one side of the pattern region and not on an opposing side of the pattern region as seen in a cross-sectional view.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a resist layer over a substrate;
contacting the resist layer with a mask,
wherein the mask comprises:
a device region having a device pattern;
an overlapping region surrounding the device region and having a light absorption material; and
a peripheral region surrounding the device region and the overlapping region, and having a light blocking material,
wherein the light blocking material is at a first level, the light absorption material is at a second level, and the device pattern is a third level, and
wherein the first, second, and third levels are at different positions;
exposing the resist layer to actinic radiation through the mask;
removing the mask from the resist layer; and
removing portions of the resist layer not exposed to the actinic radiation.

2. The method according to claim 1, wherein the actinic radiation is ultraviolet radiation.

3. The method according to claim 1, wherein the contacting the resist layer with the mask forms a pattern in the resist layer corresponding to the device pattern in the mask.

4. The method according to claim 1, wherein the exposing the resist layer to actinic radiation hardens exposed portions of the resist layer.

5. The method according to claim 1, wherein the portions of the resist layer not exposed to actinic radiation are removed by an air flushing operation.

6. The method according to claim 1, wherein the mask comprises a substrate including a planar first main surface, the device region, the overlapping region, and the peripheral region.

7. The method according to claim 6, wherein the substrate has a second surface opposing the first main surface, and the device pattern is formed in the second surface.

8. The method according to claim 7, wherein the second level is closer to the first main surface than the third level.

9. The method according to claim 8, wherein the first level is closer to the first main surface than the second level.

10. A method of manufacturing a semiconductor device, comprising:
forming a resist layer over a target layer;
contacting the resist layer with a stamp including a pattern comprising recesses and projections so that the resist layer fills the recesses in the stamp,
wherein the stamp comprises:
an ultraviolet light transmissive substrate having a first main surface, a second surface opposing the first main surface, a third surface opposing the first main surface, and a fourth surface opposing the first main surface;
a first pattern region and a second pattern region in the second main surface;
a light absorption layer disposed over the third surface; and
an opaque layer disposed over the fourth surface,
wherein the fourth surface is closer to the first main surface than the third surface, and the third surface is closer to the first main surface than the second main surface;
exposing the resist layer to actinic radiation through the stamp thereby curing the resist layer exposed to the actinic radiation;
removing the stamp from the resist layer thereby providing a pattern in the resist layer disposed over the target layer; and
removing portions of the resist layer not exposed to the actinic radiation.

11. The method according to claim 10, wherein the resist layer comprises a plurality of resist droplets.

12. The method according to claim 11, wherein the resist droplets are formed by an inkjet operation.

13. The method according to claim 11, further comprising transferring the pattern in the resist layer into the target layer.

14. The method according to claim 13, wherein the transferring the pattern comprises an etching operation.

15. The method according to claim 10, wherein the ultraviolet light transmissive substrate comprises a glass or a silicone.

16. A mask, comprising:
a device region including a device pattern;
an overlapping region surrounding the device region and having a light absorption material; and
a peripheral region surrounding the device region and the overlapping region, and having a light blocking material,
wherein the light blocking material is at a first level, the light absorption material is at a second level, and the device pattern is at a third level, and
wherein the first, second, and third levels are at different positions.

17. The mask of claim 16, wherein the mask comprises a substrate including the device region, the overlapping region, and the peripheral region.

18. The mask of claim 16, wherein the substrate has a planar first main surface and a second surface opposing the first main surface, and the device pattern is formed in the second surface.

19. The mask of claim 18, wherein the second level is closer to the first main surface than the third level.

20. The mask of claim 19, wherein the first level is closer to the first main surface than the second level.
